(19) United States
(12) Patent Application Publication
(10) Pub. No.: US 2025/0349777 A1
(43) Pub. Date: Nov. 13, 2025

(54) ELECTRONIC COMPONENT AND MANUFACTURING METHOD THEREOF

(71) Applicant: SILICONWARE PRECISION INDUSTRIES CO., LTD., Taichung City (TW)

(72) Inventors: Ting-Hao CHEN, Taichung City (TW); Hsuan-Jen WANG, Taichung City (TW); Wei-Shen HUNG, Taichung City (TW); Hsiao-Ping LAI, Taichung City (TW)

(73) Assignee: SILICONWARE PRECISION INDUSTRIES CO., LTD., Taichung City (TW)

(21) Appl. No.: 18/746,714

(22) Filed: Jun. 18, 2024

(30) Foreign Application Priority Data
May 9, 2024 (TW) 113117232

(51) Int. Cl. H01L 23/00; H01L 21/683; H01L 23/498; H01L 25/065

(52) U.S. Cl. CPC H01L 24/16; H01L 21/6836; H01L 24/81; H01L 24/97; H01L 23/49811; H01L 23/49838; H01L 25/0655; H01L 2224/16225; H01L 2224/81395; H01L 2224/8191; H01L 2224/97; H01L 2924/1532

(57) ABSTRACT

An electronic component and a manufacturing method thereof are provided, in which a plurality of conductive bumps are covered by a protective layer on a second side of a base material, and then a plurality of the electronic components are bonded on a tape of a carrier via the protective layer thereof, so that the protective layer made of such as water-soluble adhesive can cover each of the conductive bumps, and the protective layer can be removed in a subsequent process. Therefore, even if the distance between the conductive bumps becomes smaller with the requirement for miniaturization so that the tape of the carrier does not cover each of the conductive bumps, the conductive bumps will not have adhesive residue issue, such that the electronic component can be designed to meet miniaturization requirements.

### BACKGROUND

### 1. Technical Field

The present disclosure relates to a semiconductor packaging technology, and more particularly, to an electronic component that is conducive to miniaturization design and a manufacturing method thereof.

### 2. Description of Related Art

With vigorous development of portable electronic products in recent years, various related products are gradually developing towards the trend of high density, high performance and compactness (being light, thin, short and small), and various types of packaging processes are therefore being innovated in order to meet the requirements of compactness and high density.

FIG. 1A to FIG. 1E are schematic cross-sectional views showing a manufacturing method of a conventional electronic component 1.

As shown in FIG. 1A, an electronic body 10 and a circuit structure 13 disposed on the electronic body 10 are provided. A plurality of first conductive bumps 11 are formed on the electronic body 10, and the plurality of first conductive bumps 11 are covered by a first encapsulating layer 12. A plurality of second conductive bumps 14 are formed on the circuit structure 13, and the plurality of second conductive bumps 14 are covered by a second encapsulating layer 15. During the manufacturing process, the circuit structure 13, the second conductive bumps 14 and the second encapsulating layer 15 are firstly manufactured on the electronic body 10, then a first carrying member 8 is disposed on the second encapsulating layer 15, and then the first conductive bumps 11 and the first encapsulating layer 12 are manufactured, and a second carrying member 9 is finally disposed on the first encapsulating layer 12.

As shown in FIG. 1B, the first carrying member 8 and the second encapsulating layer 15 are removed to expose the second conductive bumps 14.

As shown in FIG. 1C, a singulation process is performed to obtain a plurality of the electronic components 1.

As shown in FIG. 1D, the plurality of electronic components 1 are bonded onto a tape 7 of a carrier via the second conductive bumps 14 thereof.

As shown in FIG. 1E, the second carrying member 9 and the first encapsulating layer 12 are removed.

However, in the manufacturing method of the conventional electronic component 1, a distance D between the second conductive bumps 14 becomes smaller with the requirement for miniaturization, so that the adhesive material of the tape 7 cannot fill between the second conductive bumps 14, thereby causing the tape 7 to be unable to cover each of the second conductive bumps 14, resulting in adhesive residue on the second conductive bumps 14 when the electronic component 1 is subsequently extracted, and even causing the problem of low manufacturing process yield.

Therefore, how to overcome the aforementioned problems of the prior art has become an urgent issue to be solved.

### SUMMARY

In view of the aforementioned shortcomings of the prior art, the present disclosure provides an electronic component, which comprises: a base material having a first side and a second side opposing the first side, wherein the first side of the base material has a plurality of first conductive bumps formed thereon, and the plurality of first conductive bumps are covered by a first encapsulating layer, and a plurality of second conductive bumps are formed on the second side of the base material; and a protective layer formed on the second side of the base material and covering the plurality of second conductive bumps.

In the aforementioned electronic component, the base material comprises an electronic body and a circuit structure disposed on the electronic body, wherein the first conductive bumps and the first encapsulating layer are disposed on the electronic body, and the second conductive bumps and the protective layer are disposed on the circuit structure.

In the aforementioned electronic component, the first conductive bumps and the second conductive bumps are metal pillars.

In the aforementioned electronic component, the first encapsulating layer is made of an insulating material.

In the aforementioned electronic component, the protective layer is made of a water-soluble adhesive.

The present disclosure further provides a method of manufacturing an electronic component, the method comprises: providing a base material having a first side and a second side opposing the first side, wherein the first side of the base material has a plurality of first conductive bumps formed thereon, and the plurality of first conductive bumps are covered by a first encapsulating layer, and a plurality of second conductive bumps are formed on the second side of the base material, and the plurality of second conductive bumps are covered by a second encapsulating layer; removing the second encapsulating layer to expose the plurality of second conductive bumps; forming a protective layer on the second side of the base material to cover the plurality of second conductive bumps; performing a singulation process to obtain a plurality of the electronic components; and bonding the plurality of electronic components on a tape of a carrier via the protective layer thereof.

In the aforementioned method, the base material comprises an electronic body and a circuit structure disposed on the electronic body, wherein the first conductive bumps and the first encapsulating layer are disposed on the electronic body, and the second conductive bumps and the second encapsulating layer are disposed on the circuit structure.

In the aforementioned method, the first conductive bumps and the second conductive bumps are metal pillars.

In the aforementioned method, the second encapsulating layer is made of an adhesive material.

In the aforementioned method, the first encapsulating layer is made of an insulating material.

In the aforementioned method, the protective layer is made of a water-soluble adhesive.

In the aforementioned method, the present disclosure further comprises: performing a water-washing operation to remove the protective layer after the electronic components are separated from the tape of the carrier.

It can be seen from the above that, in the electronic component and manufacturing method thereof of the present disclosure, the protective layer covers the plurality of second conductive bumps, so that when the plurality of electronic components are bonded on the carrier, the protective layer made of such as water-soluble adhesive can cover each of the second conductive bumps, and the protective layer can be removed in a subsequent process. Therefore, compared to the prior art, even if the distance between the second conductive bumps becomes smaller with the requirement for miniaturization so that the tape of the carrier does not cover each of the second conductive bumps, the second conductive bumps will not have adhesive residue issue, such that the electronic component of the present disclosure can be designed to meet miniaturization requirements.

### BRIEF DESCRIPTION OF THE DRAWINGS

FIG. 1A to FIG. 1E are schematic cross-sectional views showing a manufacturing method of a conventional electronic component.

FIG. 2A to FIG. 2F are schematic cross-sectional views showing a manufacturing method of an electronic component according to the present disclosure.

FIG. 3A to FIG. 3B are schematic cross-sectional views showing a subsequent application of FIG. 2F.

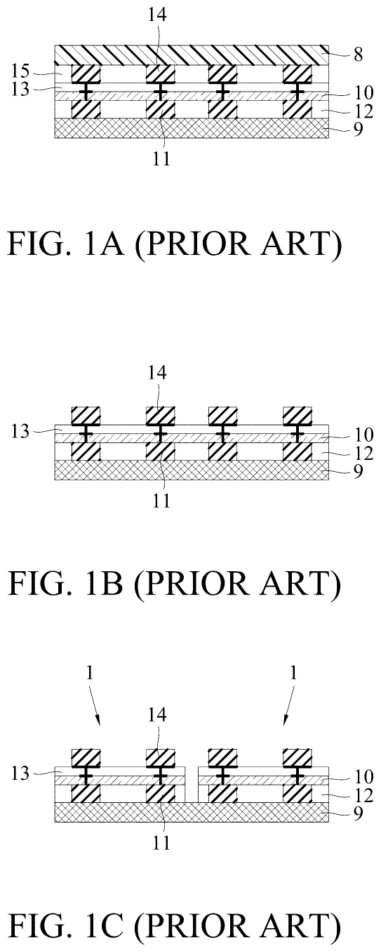

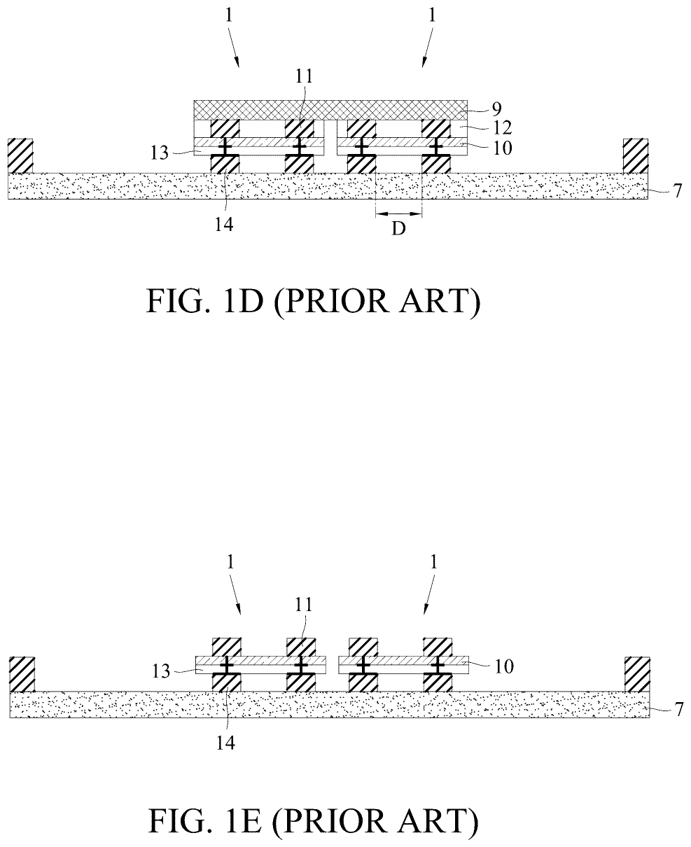

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

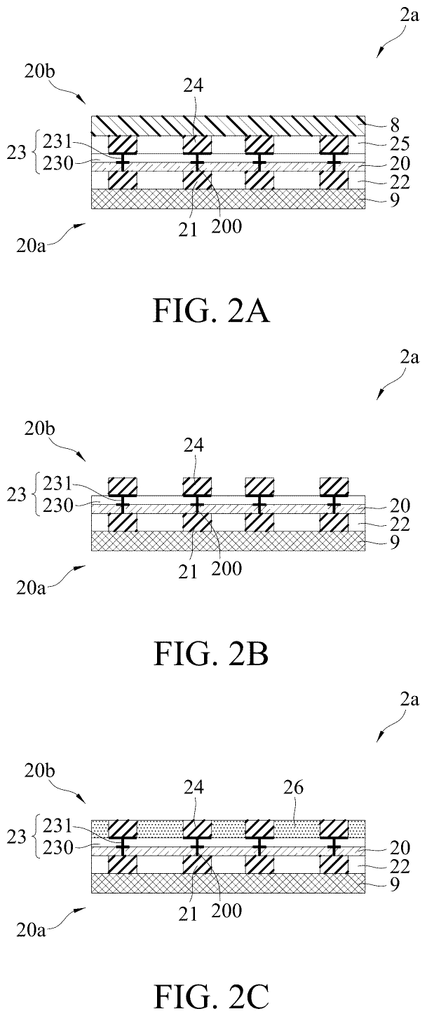

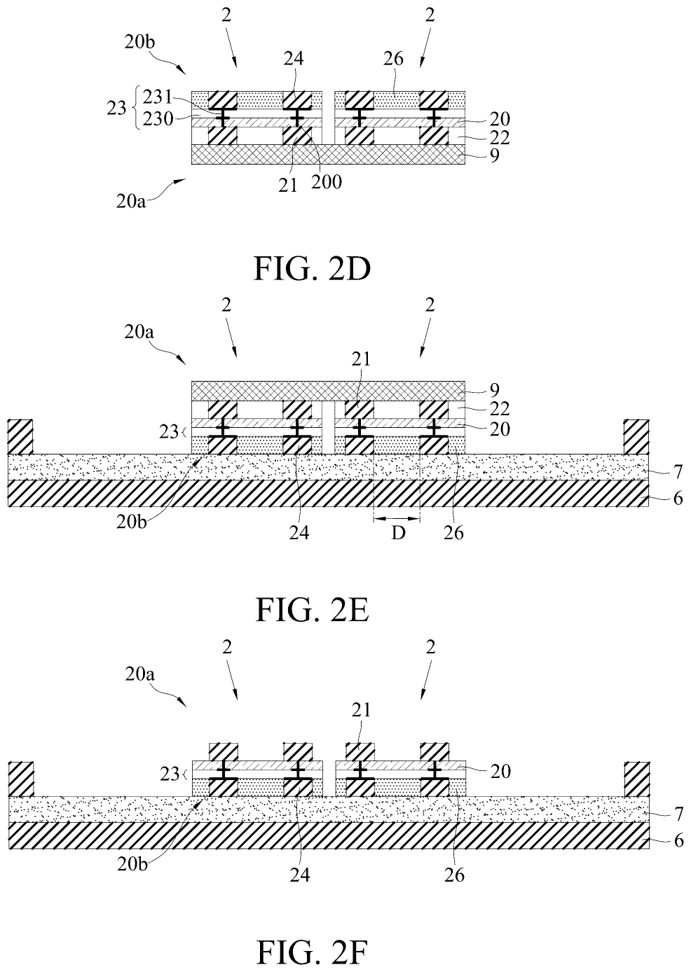

FIG. 2A to FIG. 2F are schematic cross-sectional views showing a manufacturing method of an electronic component 2 according to the present disclosure.

As shown in FIG. 2A, a base material 2a is provided and has a first side 20a and a second side 20b opposing the first side 20a. A plurality of first conductive bumps 21 are formed on the first side 20a of the base material 2a, and the plurality of first conductive bumps 21 are covered by a first encapsulating layer 22. A plurality of second conductive bumps 24 are formed on the second side 20b of the base material 2a, and the plurality of second conductive bumps 24 are covered by a second encapsulating layer 25.

The base material 2a comprises an electronic body 20 and a circuit structure 23 disposed on the electronic body 20, such that the first conductive bumps 21 and the first encapsulating layer 22 are disposed on the electronic body 20, and the second conductive bumps 24 and the second encapsulating layer 25 are disposed on the circuit structure 23.

In an embodiment, the electronic body 20 is a semiconductor chip, and a plurality of conductive vias 200 are formed in the electronic body 20 (the conductive vias 200 penetrate through the electronic body 20), such that the conductive vias 200 are electrically connected to the plurality of first conductive bumps 21. For instance, the conductive vias 200 are conductive through-silicon vias (TSVs).

Moreover, the circuit structure 23 comprises at least one dielectric layer 230 and a circuit layer 231 formed on the dielectric layer 230, such as of the specification of redistribution layer (RDL), such that the circuit layer 231 is electrically connected to the plurality of second conductive bumps 24, wherein the outermost dielectric layer 230 can be used as a solder-resist layer, and the outermost circuit layer 231 is exposed from the solder-resist layer to serve as electrical contact pads so as to bond with the plurality of second conductive bumps 24. For instance, the material for forming the circuit layer 231 is copper, and the material for forming the dielectric layer 230 is polybenzoxazole (PBO), polyimide (PI), prepreg (PP), or other dielectric materials.

Furthermore, in the manufacturing process, the circuit structure 23 and its component configuration (the second conductive bumps 24 and the second encapsulating layer 25) thereon are firstly manufactured on the electronic body 20, then a first carrying member 8 is provided on the second encapsulating layer 25, and then the first conductive bumps 21 and the first encapsulating layer 22 are manufactured, and finally a second carrying member 9 is provided on the first encapsulating layer 22. For instance, the first carrying member 8 and the second carrying member 9 are both of temporary plate specification and have no electrical properties.

The first conductive bumps 21 and the second conductive bumps 24 are metal pillars such as copper pillars. The first encapsulating layer 22 is made of insulating material and is such as a non-conductive film (NCF) or an insulating film of other types, and the second encapsulating layer 25 is made of adhesive material and is such as a tape.

As shown in FIG. 2B, the first carrying member 8 and the second encapsulating layer 25 are removed to expose the second conductive bumps 24.

As shown in FIG. 2C, a protective layer 26 is formed on the second side 20b of the base material 2a (or the circuit structure 23), so that the protective layer 26 covers the plurality of second conductive bumps 24.

In an embodiment, the protective layer 26 is made of a water-soluble adhesive that fills between the second conductive bumps 24 to fill up the space between the second conductive bumps 24, so that the protective layer 26 covers the plurality of second conductive bumps 24.

As shown in FIG. 2D, a singulation process is performed to obtain a plurality of the electronic components 2.

As shown in FIG. 2E, the plurality of electronic components 2 are bonded on a tape 7 of a carrier 6 via the protective layer 26 thereof.

As shown in FIG. 2F, the second carrying member 9 and the first encapsulating layer 22 are removed.

Hence, in the electronic component 2 and manufacturing method thereof of the present disclosure, the protective layer 26 covers around the plurality of second conductive bumps 24, so that when the plurality of electronic components 2 are bonded on the carrier 6 as shown in FIG. 2E, the protective layer 26 completely covers around each of the second conductive bumps 24. Therefore, compared to the prior art, even if a distance D between the second conductive bumps 24 becomes smaller with the requirement for miniaturization so that the tape 7 does not cover each of the second conductive bumps 24, the protective layer 26 can cover around each of the second conductive bumps 24 of the present disclosure, thereby preventing the adhesive residue issue from occurring in subsequent processes.

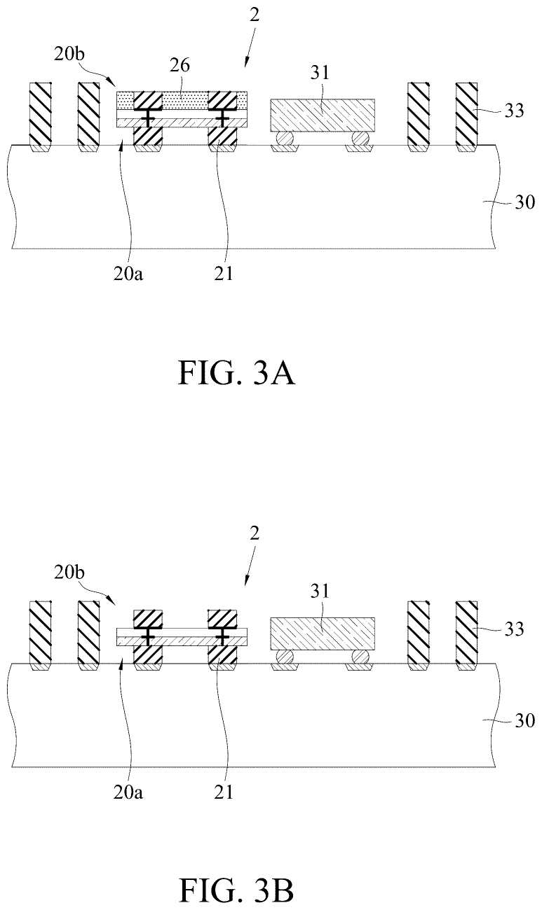

In addition, in a subsequent application, as shown in FIG. 3A to FIG. 3B, the electronic component 2 can be disposed on a package substrate 30 via the first side 20a thereof, so that the first conductive bumps 21 are electrically connected to the package substrate 30, and then a water-washing operation is performed to remove the protective layer 26 of the second side 20b.

A semiconductor chip 31 and/or a plurality of conductive pillars 33 can be provided on the package substrate 30 according to requirements to perform subsequent packaging and stacking operations.

The present disclosure further provides an electronic component 2, which comprises: a base material 2a and a protective layer 26.

The base material 2a has a first side 20a and a second side 20b opposing the first side 20a. A plurality of first conductive bumps 21 are formed on the first side 20a of the base material 2a, and the plurality of first conductive bumps 21 are covered by a first encapsulating layer 22. A plurality of second conductive bumps 24 are formed on the second side 20b of the base material 2a.

The protective layer 26 is formed on the second side 20b of the base material 2a to cover the plurality of second conductive bumps 24.

In an embodiment, the base material 2a comprises an electronic body 20 and a circuit structure 23 disposed on the electronic body 20, such that the first conductive bumps 21 and the first encapsulating layer 22 are disposed on the electronic body 20, and the second conductive bumps 24 and the protective layer 26 are disposed on the circuit structure 23.

In an embodiment, the first conductive bumps 21 and the second conductive bumps 24 are metal pillars.

In an embodiment, the first encapsulating layer 22 is made of insulating material.

In an embodiment, the protective layer 26 is made of water-soluble adhesive.

To sum up, in the electronic component and manufacturing method thereof of the present disclosure, the protective layer covers around the plurality of second conductive bumps, so that when the plurality of electronic components are bonded on the carrier, the protective layer made of such as water-soluble adhesive can cover each of the second conductive bumps, and the protective layer can be removed in a subsequent process. Therefore, even if the distance between the second conductive bumps becomes smaller with the requirement for miniaturization so that the tape does not cover each of the second conductive bumps, the second conductive bumps will not have adhesive residue issue, such that the electronic component of the present disclosure can be designed to meet miniaturization requirements.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic component, comprising:
a base material having a first side and a second side opposing the first side, wherein the first side of the base material has a plurality of first conductive bumps formed thereon, and the plurality of first conductive bumps are covered by a first encapsulating layer, and a plurality of second conductive bumps are formed on the second side of the base material; and
a protective layer formed on the second side of the base material and covering the plurality of second conductive bumps.

2. The electronic component of claim 1, wherein the base material comprises an electronic body and a circuit structure disposed on the electronic body, wherein the first conductive bumps and the first encapsulating layer are disposed on the electronic body, and the second conductive bumps and the protective layer are disposed on the circuit structure.

3. The electronic component of claim 1, wherein the first conductive bumps and the second conductive bumps are metal pillars.

4. The electronic component of claim 1, wherein the first encapsulating layer is made of an insulating material.

5. The electronic component of claim 1, wherein the protective layer is made of a water-soluble adhesive.

6. A method of manufacturing an electronic component, comprising:
providing a base material having a first side and a second side opposing the first side, wherein the first side of the base material has a plurality of first conductive bumps formed thereon, and the plurality of first conductive bumps are covered by a first encapsulating layer, and a plurality of second conductive bumps are formed on the second side of the base material, and the plurality of second conductive bumps are covered by a second encapsulating layer;
removing the second encapsulating layer to expose the plurality of second conductive bumps;
forming a protective layer on the second side of the base material to cover the plurality of second conductive bumps;
performing a singulation process to obtain a plurality of the electronic components; and
bonding the plurality of electronic components on a tape of a carrier via the protective layer thereof.

7. The method of claim 6, wherein the base material comprises an electronic body and a circuit structure disposed on the electronic body, wherein the first conductive bumps and the first encapsulating layer are disposed on the electronic body, and the second conductive bumps and the second encapsulating layer are disposed on the circuit structure.

8. The method of claim 6, wherein the first conductive bumps and the second conductive bumps are metal pillars.

9. The method of claim 6, wherein the second encapsulating layer is made of an adhesive material.

10. The method of claim 6, wherein the first encapsulating layer is made of an insulating material.

11. The method of claim 6, wherein the protective layer is made of a water-soluble adhesive.

12. The method of claim 6, further comprising: performing a water-washing operation to remove the protective layer after the electronic components are separated from the tape of the carrier.
